(19) United States
(12) Patent Application Publication
(10) Pub. No.: US 2004/0089958 A1
(43) Pub. Date: May 13, 2004

(54) Conductor wafer and substrate

(76) Inventor: Kazuhisa Arai, Tokyo (JP)

Correspondence Address: SMITH, GAMBRELL & RUSSELL, LLP, 1850 M STREET, N.W., SUITE 800, WASHINGTON, DC, 20036, US

(21) Appl. No.: 10/698,468

(22) Filed: Nov. 3, 2003

(30) Foreign Application Priority Data
Nov. 8, 2002 (JP) 2002-325165

(51) Int. Cl. H01L 23/544

(52) U.S. Cl. 257/797

(57) ABSTRACT

A semiconductor wafer having circuits formed on the front surface of a base plate, and an ID mark is formed in the interior of the base plate at a predetermined position.

### FIELD OF THE INVENTION

The present invention relates to a semiconductor wafer and a substrate for holding a plate-like workpiece such as a semiconductor wafer.

### DESCRIPTION OF THE PRIOR ART

A semiconductor wafer having circuits such as ICs or LSIs on the front surface of a base plate has an ID mark, which is used to warrant its quality or to clear up the causes of a trouble. That is, as for a semiconductor wafer having an ID mark, information on the function, history, processing conditions, size, material, lot, etc. of each circuit and information on the ingot, manufacturer, lot, purity, etc. of the base plate are recorded in a memory, and the information on the semiconductor wafer can be confirmed by collating it with the ID mark.

Further, in order to provide stiffness to, or aid in the processing of, a plate-like workpiece such as a semiconductor wafer to be processed or conveyed, a semiconductor wafer or the like may be held on a substrate in some cases. In this case, an ID mark is formed also on the substrate. That is, information on the thickness, size, material, etc. of a base plate constituting a substrate, which has an ID mark, is recorded in a memory, and the above information is confirmed by collating it with the ID mark and is utilized to set processing conditions, etc. for grinding the semiconductor wafer held on the substrate to a predetermined thickness.

Meanwhile, to form the ID mark on a semiconductor wafer and substrate, a bar code or the like is printed on the surface of the base plate by using a laser beam or the like. On this occasion, irregularities are produced on the surface of the base plate. Therefore, a problem may occur that when a contaminant enters the irregularities formed on the surface of the base plate, the ID mark cannot be detected. Further, the contaminant entering the irregularities on the surface contaminates a clean room.

### SUMMARY OF THE INVENTION

It is an object of the present invention to provide a semiconductor wafer and a substrate which enable an ID mark formed on a base plate of the semiconductor wafer or the substrate to be detected surely without being influenced by a contaminant or the like.

To attain the above object, according to the present invention, there is provided a semiconductor wafer having circuits formed on the front surface of a base plate, wherein an ID mark is formed in the interior of the base plate at a predetermined position devoid of the circuits.

According to the present invention, there is provided a substrate having a workpiece holding area in a base plate, wherein an ID mark is formed in the interior of the base plate at a predetermined position.

The ID mark is formed by converging a laser beam at a focal point in the interior of the base plate.

### BRIEF DESCRIPTION OF THE DRAWINGS

FIG. 1 is a perspective view of a semiconductor wafer constituted according to the present invention;

FIG. 2 is a diagram showing how to form an ID mark in the interior of a base plate constituting the semiconductor wafer shown in FIG. 1; and

FIG. 3 is a perspective view of a substrate constituted according to the present invention.

### DETAILED DESCRIPTION OF THE PREFERRED EMBODIMENTS

A semiconductor wafer and a substrate constituted according to a preferred embodiment of the present invention will be described in detail hereinbelow with reference to the accompanying drawings.

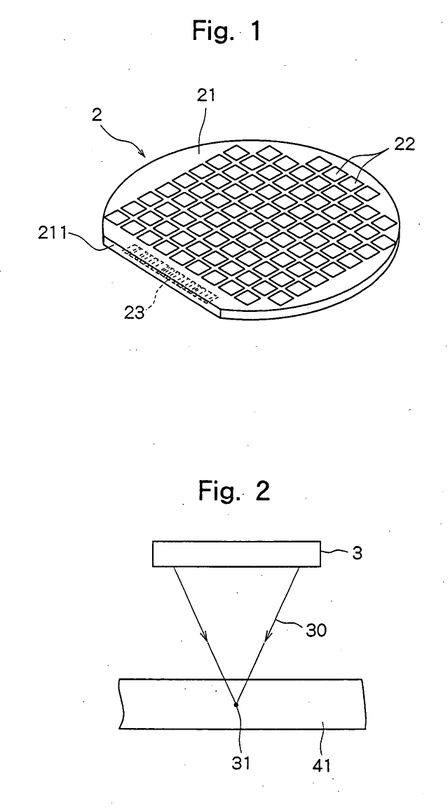

FIG. 1 is a perspective view of a semiconductor wafer constituted according to the present invention. The semiconductor wafer 2 shown in FIG. 1 has a plurality of circuits 22 formed on the front surface of a base plate 21 formed of a silicon wafer or the like. An ID mark 23 is formed in the interior of the base plate 21 at a predetermined position (in the illustrated embodiment, an orientation flat 211 side indicative of the crystal orientation of the base plate) devoid of the circuits 22. This ID mark 23 can be formed by a technique disclosed by JP-A 11-267861, for example. That is, as shown in FIG. 2, the ID mark 23 such as a bar code can be formed in the interior of the base plate 21 by converging a laser beam 30 through a FQ lens at a focal point 31 in the interior of the base plate 21. Relatively weak YAG laser beam having a wavelength of 1,064 nm may be used as the laser beam.

By forming the ID mark in the interior of the base plate 21 as described above, irregularities are not formed on the surface of the substrate 21, thereby making it possible to eliminate a detection failure or error of the ID mark caused by the entry of a contaminant in the irregularities and the contamination of each step caused by the contaminant existing in the irregularities. Since the ID mark is formed in the interior of the base plate 21, it is not erased by abrasion or etching, thereby eliminating a problem that detection in the subsequent step becomes impossible. The ID mark 23 formed in the interior of the base plate 21 is detected by an infrared camera in the processing step. Information on the function, history, processing conditions, size, material, lot, etc. of the circuits and information on the ingot, manufacturer, lot, purity, etc. of the base plate, all of which are recorded in the memory of a processing machine are collated with the information of the ID mark to set processing conditions, etc.

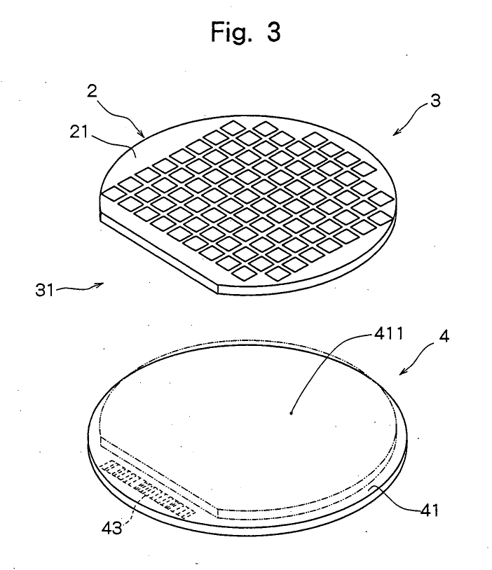

A description is subsequently given of the substrate holding a plate-like workpiece such as a semiconductor wafer with reference to FIG. 3.

A base plate 41 forming a substrate 4 shown in FIG. 3 is made of glass, synthetic resin or the like. The semiconductor wafer 2 is held in the predetermined holding area 411 of the base plate 41. An ID mark 43 is formed in the interior of the base plate 41 at a predetermined position other than the holding area 411 for holding the semiconductor wafer 2. This ID mark 43 can be formed in the same manner as the ID mark 23 formed in the interior of the base plate 21 of the above semiconductor wafer 2. By forming the ID mark 43 in the interior of the base plate 41, no irregularities exist on the surface, whereby the same effect as the above-described semiconductor wafer 2 can be obtained. The ID mark 43 is detected by an infrared camera or the like in the processing step to collate information on the thickness, size, material, etc. of the base plate stored in the memory of the processing machine with the information of the ID mark 43, so that processing conditions, etc. are set.

Since the semiconductor wafer and the substrate of the present invention are constituted as described above and the ID mark is formed in the interior of the base plate, no irregularities are existing on the surface of the base plate, thereby making it possible to eliminate an ID mark detection failure or error caused by the entry of a contaminant into the irregularities and to prevent the contamination of each step caused by a contaminant existing in the irregularities. Since the ID mark is formed in the interior of the base plate, the ID mark is not erased by abrasion or etching, thereby eliminating a problem that detection in the subsequent step becomes impossible.

What is claimed is:

1. A semiconductor wafer having circuits formed on the front surface of a base plate, wherein an ID mark is formed in the interior of the base plate at a predetermined position devoid of the circuits.

2. The semiconductor wafer according to claim 1, wherein the ID mark is formed by converging a laser beam at a focal point in the interior of the base plate.

3. A substrate having a workpiece holding area in a base plate, wherein an ID mark is formed in the interior of the base plate at a predetermined position.

4. The semiconductor wafer according to claim 3, wherein the ID mark is formed by converging a laser beam at a focal point in the interior of the base plate.
